(19) United States
(12) Patent Application Publication
(10) Pub. No.: US 2007/0126012 A1
(43) Pub. Date: Jun. 7, 2007

(54) Light-emitting element and display device

(76) Inventors: Tetsuji Omura, Ogaki-shi (JP); Masaya Nakai, Osaka (JP); Makoto Shirakawa, Osaka (JP); Shuichi Sasa, Aichi-gun (JP)

Correspondence Address: CANTOR COLBURN, LLP, 55 GRIFFIN ROAD SOUTH, BLOOMFIELD, CT, 06002, US

(21) Appl. No.: 11/602,879

(22) Filed: Nov. 21, 2006

(30) Foreign Application Priority Data
Nov. 22, 2005 (JP) 2005-337636
Nov. 22, 2005 (JP) 2005-337637

(51) Int. Cl. H01L 33/00

(52) U.S. Cl. 257/89

(57) ABSTRACT

A combined thickness of an optical distance between an anode and a cathode together with a red-light-emitting layer, a blue-light-emitting layer, and the like of a light-emitting element and the anode is set to a thickness by which red and blue light can be intensified by interference. Thus, light of necessary wavelength can be intensified, and white light can be extracted efficiently.

### CROSS-REFERENCE TO RELATED APPLICATIONS

The entire disclosures of Japanese Patent Application Nos. 2005-337636and 2005-337637, including the specifications, claims, drawings, and abstracts, are incorporated herein by reference.

### BACKGROUND OF THE INVENTION

1. Field of the Invention

The present invention relates to the adjustment of interference peak wavelength in a white-light-emitting element.

2. Related Art

Conventionally, a display device utilizing an organic EL element has been known. In the organic EL element, electric current is allowed to flow in an organic EL layer between electrodes, and light emission occurs in response to the electric current.

As the light-emitting material of the organic EL, those having red emission, blue emission, and green emission are known. Therefore, full-color display can be performed by separately coloring in RGB. In the case of a separate coloring method of RGB, since organic EL layers of each color are of different materials, a separate deposition process for each color of RGB is generally necessary, and individual masks are used for the deposition. Yield tends to lower when the number of forming processes becomes larger.

Meanwhile, constitution of a white-light-emitting layer is suggested by laminating a red (orange)-light-emitting layer and a blue-light-emitting layer to allow both the light-emitting layers to emit light. In this constitution, the white-light-emitting layer can be formed commonly for all pixels, and each pixel of RGB can be formed by color filters. Relatively difficult formation of the organic EL layer can be simplified and yield can be improved.

Moreover, in the display on a display device, in most cases white display and light emission of all colors of RGB are performed. For this reason, a display device of RGBW, where efficiency is improved by providing a white pixel in addition to each pixel of RGB, is suggested (Japanese Patent Laid-open No. 2004-127602).

In the display device of RGBW, improving the light-emitting efficiency of white color leads to overall improvement in efficiency.

Further, in both display devices of separate coloring of RGB and white light emission +color filter type, various types of layers exist on an output route of light from the organic EL element. In an active matrix type display device, which controls electric current to each organic EL element by thin film transistors (TFT) provided for each pixel, a layer on which the TFTs are formed exists along a route where light emitted from the organic EL element is out put to the outside. Therefore, there exists a problem that various types of reflection occur on the TFT layer, which interfere with the light from the organic EL element, and viewing angle dependency becomes larger.

### SUMMARY OF THE INVENTION

A white-light-emitting element according to the present invention comprises: a transparent insulating film; a transparent electrode formed on the transparent insulating film; a white-light-emitting layer formed on the transparent electrode; and a reflective layer formed on the white-light-emitting layer, and light obtained by allowing electric current to flow in the white-light-emitting layer is extracted from the transparent insulating film side. Therefore, an optical length from the surface of the transparent insulating film side of the transparent electrode to the reflective layer is preferably set to a distance having interference peaks in red and blue light.

White light can be extracted efficiently if red and blue light can be intensified by the interference.

Further, the display device according to the present invention includes: a TFT layer that includes display pixels arranged in a matrix and includes thin film transistors; a planarization layer formed on the TFT layer; and an organic EL layer formed on the planarization film. The thickness of the planarization layer is preferably sufficient to render substantially small the influence of the interference between reflected light on the TFT layer and light emission from the organic EL layer. With this constitution, the viewing angle dependency on display can be suppressed. Further, when color temperature is set so as to move in a lower direction as the viewing angle is tilted from the front, changes in color tint sensed by the human eye is reduced.

### BRIEF DESCRIPTION OF THE DRAWINGS

A preferred embodiment of the present invention will be described in further detail by reference to the following drawings, wherein:

FIG. 1 is a schematic view showing a sectional constitution of a light-emitting element.

FIG. 2 is a schematic view showing a sectional constitution of an organic EL element portion.

FIG. 3 is a schematic view showing a sectional constitution of another example of the organic EL element portion.

FIG. 4 is a graph showing the influence of interference.

FIG. 5 is a graph showing the relationship between changes in film thickness and changes in power consumption.

FIG. 6 is a view showing a sectional constitution of a top-emission-type light-emitting element.

FIG. 7 is a view showing an example of a pixel circuit.

FIG. 8 is a view showing the relationship between a viewing angle and the luminance of each color of RGB.

FIG. 9 is a view showing color temperature variations due to changes in viewing angle.

### DESCRIPTION OF PREFERRED EMBODIMENTS

Hereinafter, by reference to the drawings, a light-emitting element according to the embodiment of the present invention will be described.

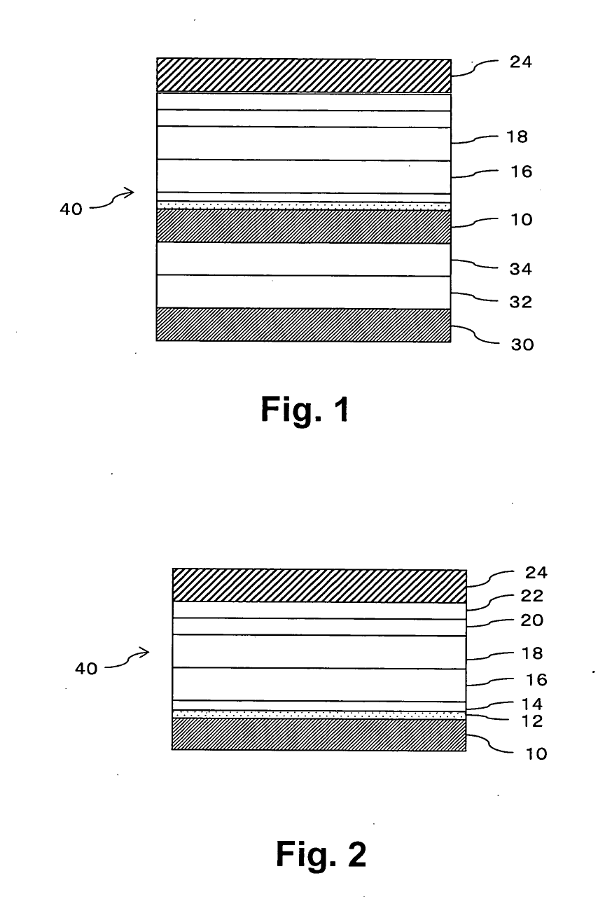

FIG. 1 is a schematic view showing the sectional constitution of the light-emitting element. In the drawing, only one light-emitting element is illustrated, but the light-emitting elements and pixel circuits driving the light-emitting elements are arranged in a matrix to constitute a display device. Further, layers such as a glass substrate, a light-emitting layer, and a cathode, which can be commonly formed for all pixels, are commonly formed for all pixels.

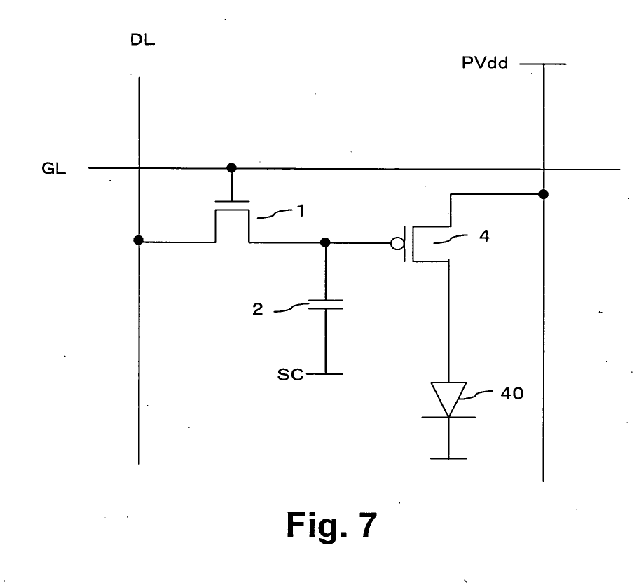

A TFT (thin film transistor)/wiring layer 32 including a pixel circuit and various types of wirings is formed on a glass substrate 30. The circuit shown in FIG. 7, for example, is used as the pixel circuit. A switching TFT 1 controls the input of data signals from a data line DL in response to control signals from a gate line GL. Data voltage input by the switching TFT 1 is accumulated in a capacitor 2. A drive TFT 4 turns on in response to the data voltage accumulated in a holding capacitor, and drive current corresponding to the data voltage is supplied from a power source line PVdd to an EL element 40. It should be noted that the other end of the capacitor 2 is connected to a capacitor line SC. Further, the EL element 40 is formed on a planarization layer 34 as described later. Herein, many suggestions are made for the pixel circuit, and modifications of various types, such as including a threshold value compensation circuit of the drive TFT, are possible.

Further, the planarization layer 34 made of acrylic resin or the like is formed on the TFT/wiring layer 32.

The organic EL element 40 is formed on the planarization layer 34. The organic EL element 40 includes an anode 10, a red light-emitting layer 16, a blue-light-emitting layer 18, and a cathode 24.

Herein, the anode 10 is formed for each pixel, but the red-light-emitting layer 16, the blue-light-emitting layer 18, the cathode 24, and the like are basically formed as common layers for all pixels.

Herein, by reference to FIG. 2, description will be provided for a specific constitution example of the organic EL element 40. A hole transport layer 14 is provided on the anode 10 made of a transparent conductor, via a hole injection layer 12. In this example, IZO (Indium Zinc Oxide) is used for the anode 10, but ITO (Indium Tin Oxide) or the like may also be used. Further, in this example, CFx is used for the hole injection layer 12, and a layer employing as a host NPB (N,N′-di(naphthalene-1-yl)-N,N′-diphenyl-benzycin), which is a triallylamine derivative or a triphenylamine derivative, is used as the hole transport layer 14.

The red-light-emitting layer 16 and the blue-light-emitting layer 18 are sequentially formed on the hole transport layer 14. In the red-light-emitting layer 16, NPB, being a triallylamine derivative or a triphenylamine derivative, is used as the host; tertiary-butyl-substituted dinaphtylanthracene (TBADN) is used as dopant 1; and 5,12-bis(4-(6-methylbenzothiazol-2-yl)phenyl)-6,11-diphenyl naphthacene (DBZR) is used as dopant 2. Further, in the blue-light-emitting layer 18, tertiary-butyl-substituted dinaphtylanthracene (TBADN) is used as the host; NPB being a triallylamine derivative or a triphenylamine derivative is used as the dopant 1; and 1,4,7,10-tetra-tertiary-butylperylene (TBP) is used as the dopant 2.

A first electron transport layer 20 and a second electron transport layer 22 are provided on the blue-light-emitting layer 18, and the cathode 24 is provided on these layers.

Tris (8-hydroxyquinolinato) aluminum (Alq) is used for the first electron transport layer 20, and a phenanthroline derivative is used for the second electron transport layer 22. Further, aluminum (Al) provided with LiF on its surface is used for the cathode 24.

As described, the organic EL element 40 of this embodiment has the red-light-emitting layer 16 and the blue-light-emitting layer 18 between the electrodes of the anode 10 and the cathode 24, and white light emission is created by causing light emission in both the light-emitting layers (16, 18). Therefore, recombination of holes supplied from the anode 10 and electrons supplied from the cathode 24 occurs in an area near the interface of the light-emitting layers (16, 18), light emission is created in both the light-emitting layers (16, 18), and the white light is output from the glass substrate 30. It should be noted that in practice RGB filters are provided for each pixel in order to perform full-color display, and in the case of the RGBW type, pixels outputting white color, which are not provided with a color filter, are also provided.

Herein, in this embodiment, the two light-emitting layers (16, 18) emit light. Therefore, light emission is created in the area near the interface of the two light-emitting layers (16, 18), and the boundary between the light-emitting layers (16, 18) becomes a light-emitting interface. This is a required condition for creating light emission in both the light-emitting layers (16, 18). Then, a portion of the light created near the interface is directly output and a portion of the light is reflected by the cathode 24. In other words, the cathode 24 is aluminum, and the light emitted from the light-emitting layers (16, 18) cannot pass through the cathode 24 but is reflected.

Therefore, the light output from the organic EL element 40 is synthesized light of the light directly emitted from the interface between the light-emitting layers (16, 18) and the light reflected by the cathode 24, and interference occurs between the two types of light.

Although, if necessary, visible light can be intensified by the interference, visible light having a predetermined wavelength dependent on a distance from the interface to the cathode 24 is usually attenuated by the interference.

In this embodiment, the light directly output interferes with the light reflected on the reflective layer, and the reduction in visible light is prevented by reducing the distance from the interface to the surface (reflection surface) of the cathode 24.

Specifically, the optical distance from the interface between the red-light-emitting layer 16 and the blue-light-emitting layer 18 in the organic EL element 40 to the surface of the cathode 24 is set to 100 nm or less. Thus, the intensity reduction of the blue wavelength caused by interference is suppressed. It should be noted that the attenuation of visible light, which becomes a problem in display recognized by an observer, should be substantially eliminated, so that the optical distance from the interface between the red-light-emitting layer 16 and the-blue light-emitting layer 18 to the surface of the cathode 24 should be an optical length equal to ¼ or less the shortest wavelength of the visible light. Moreover, as an optical length slightly longer than the optical length equal to ¼ or less the shortest wavelength of the visible light, an optical length where attenuation occurs due to interference in the blue wavelength of a region near the ultraviolet range is also acceptable.

It should be noted that the refractive index of the organic layer is approximately 1.6 to 1.9, and the thickness of each layer should be determined by reference to actual refractive index.

Further, the blue-light-emitting layer 18 and the like exist between the interface and the cathode 24, and the distance is preferably set to approximately 50 nm to 60 nm.

Further, the refractive index of ITO and that of IZO, which constitute the anode 10, are approximately 1.8 to 2.1. Meanwhile, the planarization layer 34 formed under the anode 10 is usually formed of acrylic resin or the like as described above, and its refractive index is approximately 1.5 to 1.6, whereby the difference in refractive index between the anode 10 and the planarization layer 34 is relatively large, and reflection easily occurs on the interface.

Therefore, the light reflected on the interface between the anode 10 and the planarization layer 34 is reflected by the cathode 24 and interferes with the light directly output from the interface.

In this embodiment, the distance (optical length) from the interface between the anode 10 and the planarization layer 34 to the surface of the cathode 24 is set by the interference at this point in order to intensify the red and blue light. In other words, the optical length from the interface on which reflection occurs to the cathode 24 being the reflective layer is set such that peaks of interference waveform exists correspond to the red and blue wavelengths.

Herein, the thickness of organic layers in the organic EL element 40 is limited to some extent for each layer, for the purpose of efficient light emission. On the other hand, the thickness of the anode 10 made of the transparent material can be changed relatively freely. Therefore, the optical length is preferably set by varying the thickness of the anode 10. Specifically, the thickness of the anode 10 should be adjusted within the range of 100 nm to 250 nm.

Meanwhile, a condition for intensifying the light of a predetermined wavelength λ by interference is that phases of light from different routes become identical, and as an example, there is considered setting of an optical distance Σnd from the interface between the anode 10 and the planarization layer 34 to the surface of the cathode 24 to an optical length of ½ the wavelength λ of light to be intensified. In other words, Σnd=·λ/2 (n is refractive index, m is integer of 1 or more) holds. Accordingly, light of a particular wavelength can be intensified by the interference of reflected light by the cathode 24. For example, when Σnd is set so as to intensify the light having the wavelength of 440 nm in the case of m=3, light having the wavelength of 660 nm is also intensified in the case of m=2. Thus, blue that is originally necessary and light near red can be intensified by interference, and white light can be extracted efficiently. Specifically, in the above-described constitution, the total thickness of the anode 10 and the organic layers is preferably set to approximately 330 nm to 430 nm.

As described, an effective white-light-emitting element can be obtained by setting the optical distance Σnd from the interface between the anode 10 and the planarization layer 34 to the surface of the cathode 24 to a distance at which blue light and red light, which are required to obtain white light, can be intensified.

It should be noted that the refractive indices of the organic layers such as the red-light-emitting layer 16 and the blue-light-emitting layer 18, which are formed between the anode 10 and the cathode 24, are approximately 1.6 to 1.9, and reflection on the anode 10 is small.

Moreover, the thickness of the planarization layer 34 is preferably made thicker. For example, the optical length of the planarization layer 34 is preferably set to 1 μm or more, particularly preferably to 1.3 μm or more. As described, as the thickness of the planarization layer 34 increases, interference caused by reflection on the interfaces of the planarization layer is gradually made flat, so that a sharp interference peak tends not to appear. Therefore, by making the planarization layer 34 thicker, an interference condition (peak) is not changed by the reflection or the like on the TFT/wiring layer 32 being a layer under the same, whereby interference peaks for red and blue can be maintained.

In the case where electric current efficiency of light emission from each light-emitting element of RGBW is 1 when the TFT/wiring layer 32 does not exist, the electric current efficiencies in the respective light-emitting element of RGBW when the planarization layer 34 is not provided become 0.91, 0.79, 0.95 and 1.12. As described, if the planarization layer 34 is not provided, light having a particular wavelength (green in this case) is attenuated due to the influence of the interference by the TFT. Therefore, condition optimization including not only an EL condition but also the TFT becomes necessary for the attenuation caused by the interference.

On the other hand, in the case where the above-described planarization layer 34 is relatively thick; that is, has a thickness of 1.0 μm or more (1.3 μm), the respective electric current efficiencies of RGBW become 0.98, 0.98, 0.98 and 1.03. Thus, it is confirmed that the planarization layer 34 can eliminate the influence of interference by the TFT in the layer under the planarization film 34. As described, by providing the thick planarization film 34, the influence by dispersion of the film thickness of TFT is reduced, and apparatus margin can be improved.

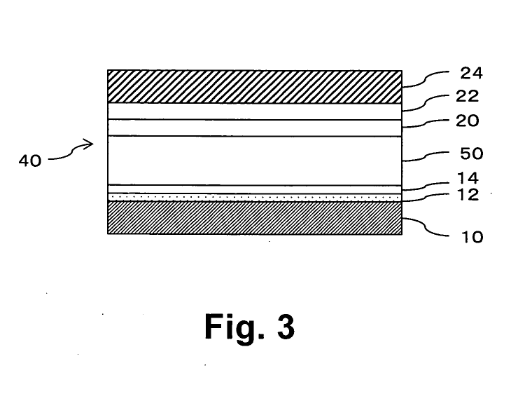

FIG. 3 shows the constitution of the organic EL element 40 according to another embodiment. In this example, a single-layer white-light-emitting layer 40 is employed instead of the red-light-emitting layer 16 and the blue-light-emitting layer 18.

In the white-light-emitting layer 40, tertiary-butyl-substituteddinaphtylanthracene (TBADN) isused as the host, 1,4,7,10-tetra-tertiary-butylperylene (TBP) is used as the blue dopant, and 5,12-bis(4-(6-methylbenzothiazol-2-yl)phenyl)-6,11-diphenyl naphthacene DBZR) is used as the red dopant, for example. When such a white-light-emitting layer 40 is used, the interface between the red-light-emitting layer 40 and the hole transport layer 14 becomes a light-emitting interface creating light emission.

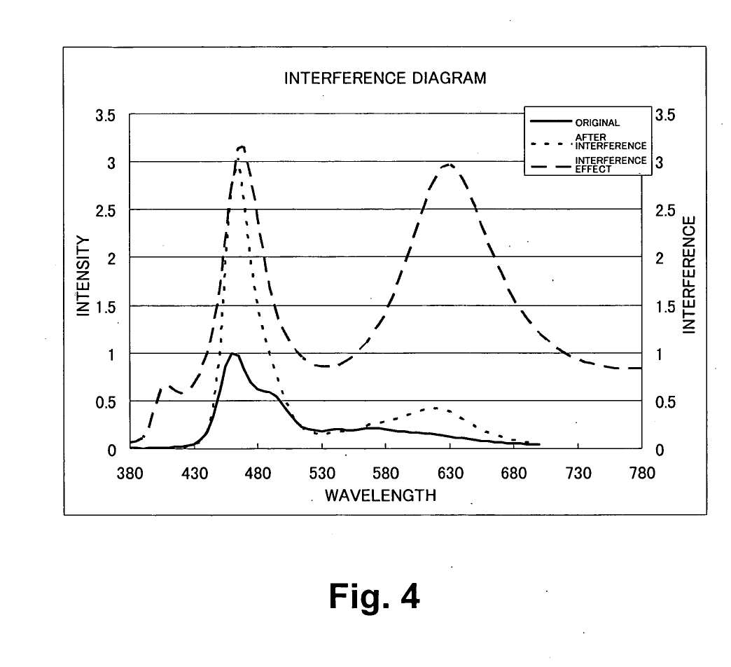

FIG. 4 shows the wavelength characteristics of the white light outputted from the light-emitting layers (16, 18), light after interference, as well as the interference effect in the light-emitting element of this embodiment. The graph shows that the blue light and the red light are intensified by the interference effect.

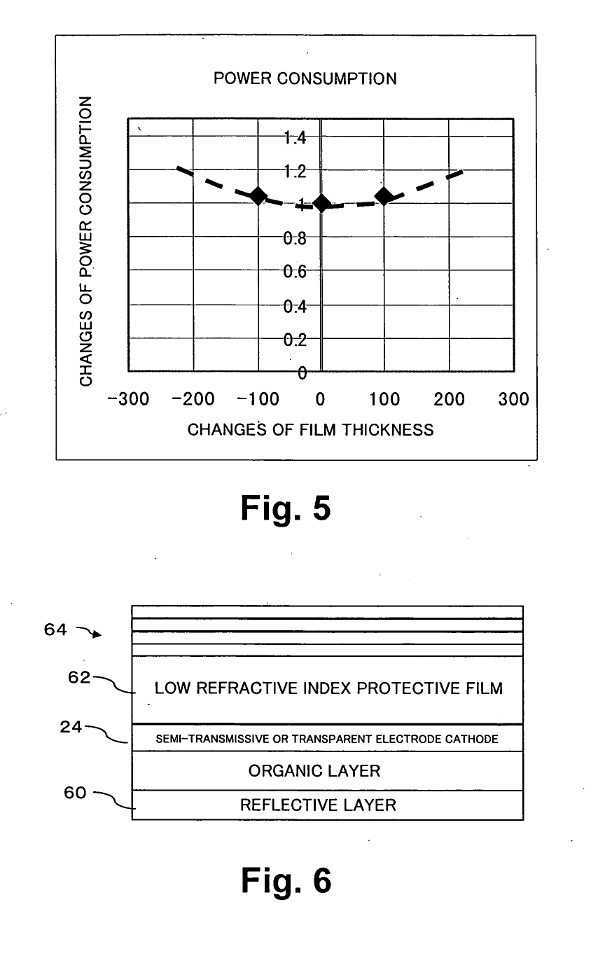

FIG. 5 is the view showing the power consumption that is required in order to obtain necessary white light intensity in the case where the optical distance from the interface between the anode 10 and the planarization layer 34 to the surface of the cathode 24 is changed. The graph shows that power consumption is suppressed in the case where the distance is set to a predetermined film thickness.

FIG. 6 shows a schematic view of a top-emission-type EL element. As shown, in the case of the top-emission type, the transparent anode 10 is formed on the reflective layer of aluminum or the like; organic layers such as the hole transport layer 14, the red-light-emitting layer 16, and the blue-light-emitting layer 18 are formed above the same; and as the cathode 24 on these elements, a semi-transmissive or a transparent electrode that allows transmission of light is formed. A thin metal material is employed as the semi-transmissive material, and ITO, IZO or the like is employed as the transparent material.

Further, on the cathode, a low refractive index protective film 62 and a laminated protective film 64 are formed. The low refractive index protective film 62 is formed of SiO₂, and the laminated protective film 64 is formed of a laminated film of SiN and SiO₂, or the like.

It should be noted that the organic layers can be constituted in the same manner as in the case of the bottom-emission-type EL element.

In the case of the top emission type as well, the distance from the light-emitting interface to the reflective layer 60 must be a sufficiently short distance to prevent attenuation of -output visible light by interference. Particularly, in the case where the anode 10 is the transparent electrode in the top-emission type, the anode 10 is included in the distance to the reflective layer 60, whereby the anode 10 must become relatively thin.

Moreover, occurrence of the adverse effect of interference due to the reflected light by the laminated protective film 64 or the like can be prevented by setting the low refractive index protective film 62 to 1 μm or more.

Further, reflection occurs on the interface between the low refractive index protective film 62 and the cathode 24. Therefore the optical length from the interface to the reflective layer 60 is preferably set to a distance at which light of a particular wavelength can be intensified in the same manner as in the above-described bottom-emission type.

As described above, in this embodiment the planarization layer 34 is formed as thick as 1 μm or more. Particularly, the thickness of the planarization layer 34 is preferably 1.5 μm. As described, as the thickness of the planarization layer 34 increases, various types of routes are secured for light that passes the layer in a diagonal direction, and a sharp interference peak tends not to appear. Therefore, by making the planarization layer 34 thicker, influence of reflection or the like on the TFT/wiring layer 32 being the layer thereunder is reduced, and peak occurrence of visible light having a particular wavelength due to this interference can be suppressed. With this method, changes in color tint due to changes in viewing angle can be reduced. In other words, when a particular wavelength is intensified by interference, the particular wavelength changes by the optical path length, so that it has large viewing angle dependency. Then, by making the planarization film sufficiently thick to reduce the influence of interference by the reflection on the TFT/wiring layer, the viewing angle dependency regarding display can be reduced.

Meanwhile, in the case where a color filter is arranged on or under the planarization film (in a normal case, the color filter is covered by the planarization film), the combined thickness of the color filter and the planarization film should be 1.5 μm as described above. For example, in the case of a RGBW display device having a white-light-emitting layer, color filters are provided for the pixels of RGB but are not provided for the pixels of W. Further, the color filters are normally formed as layers under the planarization film.

Although the thickness of the planarization film should be 1.5 μm or more, a thicker planarization film is better for the purpose of improving viewing angle dependency. On the other hand, making the planarization film become thicker requires additional material cost, and in this case attenuation of light becomes larger as well. Therefore, a thinner film is desirable and the thickness is preferably 5 μm or less, more preferably 3 μm or less.

Further, the refractive indices of ITO and IZO that constitute the anode 10 are approximately 1.8 to 2.1. Meanwhile, as described above, the planarization layer 34 formed under the anode 10 is usually formed of acrylic resin or the like, and its refractive index is approximately 1.5 to 1.6. The difference in refractive index between the anode 10 and the planarization layer 34 is relatively large, and reflection easily occurs on the interface. Therefore, light reflected on the interface between the anode 10 and the planarization layer 34 is reflected by the cathode 24, and interferes with the light directly output from the interface. In this embodiment, the distance (optical length) from the interface between the anode 10 and planarization layer 34 to the surface of the cathode 24 is set so as to intensify blue light by the interference at this point. In other words, the optical length from the interface on which reflection occurs to the cathode 24 that becomes the reflective layer is set such that the peak of interference waveform exists in the blue wavelength.

For example, the thickness is set as follows.
(A) In the case of a WRGB method, assuming that a distance from the bottom surface of the anode to the bottom surface of the cathode is 50 nm to 600 nm, the following are set: (1) an anode (IZO) of approximately 160 nm, an organic layer of approximately 210 nm, (2) an anode (IZO) of approximately 30 nm, an organic layer of approximately 200 nm, and (3) an anode (IZO) of approximately 20 nm, an organic layer of approximately 70 nm. Accordingly, the peak of interference is set in blue, and the viewing angle changes of blue become larger.
(B) In the case of an RGB (white-light-emitting layer +color filter) method, assuming that a distance from the bottom surface of the anode to the bottom surface of the cathode is 50 nm to 600 nm, the following are set: (1) an anode (IZO) of approximately 160 nm, an organic layer of approximately 230 nm, (2) an anode (IZO) of approximately 30nm, an organic layer of approximately 210 nm, and (3) an anode (IZO) of approximately 20 nm, an organic layer of approximately 80 nm. Accordingly, the peak of interference is set in blue, and the viewing angle changes of blue become the largest.
(C) In the case of an RGB (light emission of each color of RGB) method, a distance from the bottom surface of the anode to the bottom surface of the cathode is set as follows in the pixels of each color of RGB. (R) 120, 260, 400 nm, (G) 130, 270, 410 nm, (B) 110, 250, 390 nm Accordingly, the peak of interference is set in blue in the blue pixels, but the peaks of interference do not match in red and green.

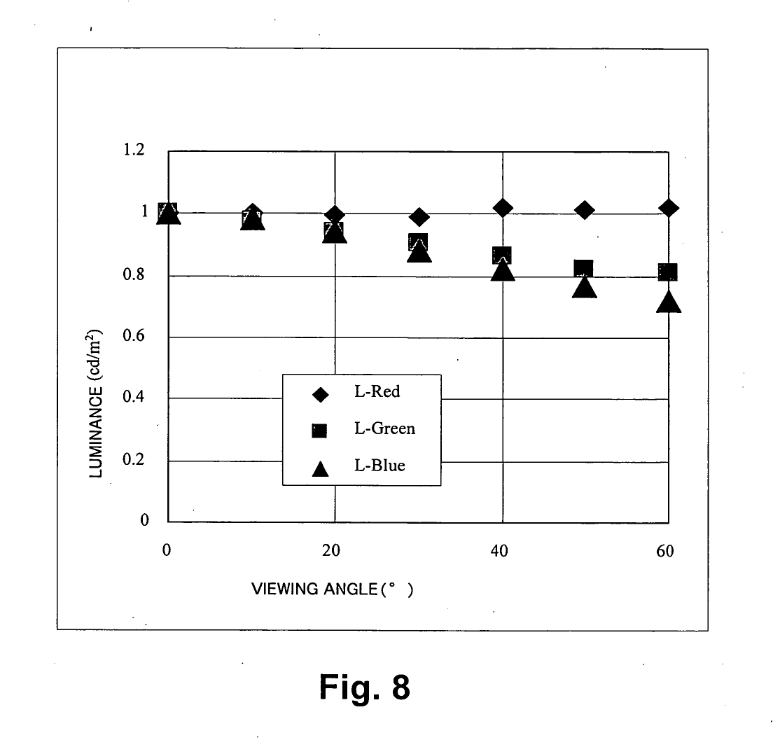

In this manner, the blue light is intensified by interference in this embodiment. Herein, the interference has a large viewing angle dependency, because it is influenced by its optical path length. Therefore, when blue is intensified by the interference as described above, blue is relatively weakened by the viewing angle. In other words, as shown in FIG. 8, blue reduces the most due to the viewing angle. It should be noted that FIG. 8 shows characteristics in the case where a color filter was provided for the white-light-emitting layer of the above-described (B), and pixels of each color of RGB were formed.

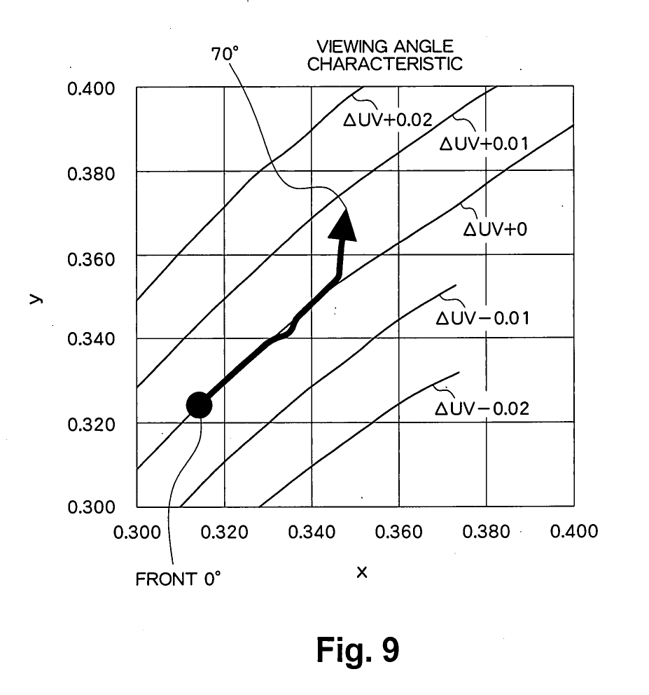

Then, as blue is weakened by the shifting of the viewing angle in a diagonal direction from the front, changes in Auv on a color temperature coordinate become very small as shown in FIG. 9. The black circle in FIG. 9 shows color temperature when seen from the front, and the black triangle shows the color temperature at the viewing angle of 70°. As described, according to this embodiment, color temperature changes on the deviation of Δuv=0substantially when the viewing angle is changed. Thus, color changes of white become smaller, and color tone changes caused by the viewing angle are reduced. Further, by setting Auv to within ±0.02, the human eye encounters difficulty in recognizing the color changes by the viewing angle, and the viewing angle dependency of display can be reduced.

Meanwhile, although in the above-described example the anode and the organic layers were set to the optical path length suffering from interference, but the color filters are also included in the optical path length depending on the arrangement of the color filters. Furthermore, in the case where no planarization layer is provided, the TFT layer is also included in the optical path length.

As described, according to this embodiment, the output light from the front is set to an interference condition where blue is intensified. Thus, blue is weakened by interference when seen diagonally and changed in a direction where color temperature lowers, so that the changes in color tint in response to the changes in viewing angle can be reduced.

What is claimed is:

1. A light-emitting element, comprising:
a transparent insulating film;
a transparent electrode formed on the transparent insulating film;
a white-light-emitting layer formed on the transparent electrode; and
a reflective layer formed on the white-light-emitting layer, wherein
an optical length from the surface of the transparent insulating film side of said transparent electrode to said reflective layer is set to a distance having peaks of interference in red and blue light.

2. The light-emitting element according to claim 1, wherein
the optical distance from a light-emitting interface of said white-light-emitting layer to said reflective layer is 100 nm or less.

3. The light-emitting element according to claim 2, wherein
said light-emitting interface is an interface between the white-light-emitting layer and a hole transport layer.

4. The light-emitting element according to claim 2, wherein
said white-light-emitting layer is constituted by laminating a red-light-emitting layer and a blue-light-emitting layer.

5. The light-emitting element according to claim 4, wherein
said light-emitting interface is an interface between the red-light-emitting layer and the blue-light-emitting layer.

6. The light-emitting element according to claim 1, wherein
said reflective layer is a reflective electrode facing the transparent electrode.

7. The light-emitting element according to claim 1, wherein the optical length of the thickness of said transparent electrode is 200 nm to 500 nm.

8. The light-emitting element according to claim 1, wherein the film thickness of said transparent insulating film is 1 μm or more.

9. A display device including display pixels arranged in a matrix, wherein
the light-emitting elements according to claim 1 are arranged on said display pixels in a matrix.

10. A display device that includes display pixels arranged in a matrix, said device comprising:
a TFT layer including thin film transistors;
a planarization layer formed on the TFT layer; and
an organic EL layer formed on the planarization film, wherein
the thickness of said planarization layer is sufficient to substantially reduce the influence of interference between reflected light on said TFT layer and light emission on said organic EL layer.

11. The display device according to claim 10, wherein
said organic EL layer is a white-light-emitting layer, and
color display is performed when said planarization film includes color filter layers of red, green, and blue.

12. The display device according to claim 10, wherein the thickness of said planarization layer is 1.5 μn or more.

13. The display device according to claim 10, wherein
by tilting a viewing angle from the front, color temperature of white, which is adjusted on the front, is set so as to vary within the range of Δuv=±0.02 or less.

14. The display device according to claim 13, wherein
the output route of light output from said organic EL layer is set so as to intensify blue light by interference.
